(19) United States
(12) Patent Application Publication
(10) Pub. No.: US 2020/0328584 A1
(43) Pub. Date: Oct. 15, 2020

(54) ARCING FAULT RECOGNITION UNIT

(71) Applicant: SIEMENS AKTIENGESELLSCHAFT, München (DE)

(72) Inventors: Peter SCHEGNER, Dresden (DE); Jörg MEYER, Dresden (DE); Peter SCHEGNER, Dresden (DE)

(21) Appl. No.: 16/305,132

(22) PCT Filed: May 31, 2016
(86) PCT No.: PCT/EP2016/062274

§ 371 Date: Nov. 28, 2018

(51) Int. Cl. H02H 1/00; H02H 3/28; G01R 31/12; H02H 3/50

(52) U.S. Cl. CPC H02H 1/0015; H02H 3/50; G01R 31/1272; H02H 3/28

(57) ABSTRACT

An arcing fault recognition unit for an electric low-voltage circuit, includes at least one voltage sensor for periodically ascertaining electric voltage values in the electric circuit, the voltage sensor being connected to an analysis unit which is designed in such a way that an arcing fault recognition signal is output when a variation in the voltage over time exceeds a first threshold value or drops below a second threshold value.

### PRIORITY STATEMENT

This application is the national phase under 35 U.S.C. § 371 of PCT International Application No. PCT/EP2016/062274 which has an International filing date of May 31, 2016, which designated the United States of America, the entire contents of which are hereby incorporated herein by reference.

### FIELD

Embodiments of the invention generally relate to a fault arc detection unit, a circuit breaker, a short-circuiter and a method for fault arc detection.

### BACKGROUND

In low voltage circuits or low voltage installations, or low voltage systems, i.e. circuits for voltages up to 1000 volts AC or 1500 volts DC, short circuits are for the most part linked to fault arcs that arise, such as parallel or series fault arcs. Particularly in powerful distribution installations and switchgear, these can lead to devastating destruction of resources, installation parts or complete switchgear if shutdown is not fast enough. To avoid lengthy and extensive failure of the power supply and reduce injury to persons, it is necessary to detect and extinguish such fault arcs, in particular high-current or parallel fault arcs, in a few milliseconds. Conventional protection systems of power supply installations (e.g. fuses and circuit breakers) cannot afford reliable protection under the obligatory time constraints.

In this context, circuit breakers means in particular switches for low voltage. Circuit breakers, in particular in low voltage installations, are usually used for currents of from 63 to 6300 amps. More specifically, enclosed circuit breakers, such as molded case circuit breakers, are used for currents of from 63 to 1600 amps, in particular from 125 to 630 or 1200 amps. Exposed circuit breakers, such as air circuit breakers, are used in particular for currents of from 630 to 6300 amps, more specifically from 1200 to 6300 amps.

Circuit breakers within the meaning of embodiments of the invention can have in particular an electronic trip unit, also referred to an ETU for short.

Circuit breakers monitor the current flowing through them and interrupt the electric current or flow of energy to an energy sink or a load, referred to as tripping, when current limit values or current/period limit values, i.e. when a current value is present for a certain period, are exceeded. Trip conditions can be ascertained and a circuit breaker tripped by means of an electronic trip unit.

Short-circuiters are specific devices for shorting lines or power rails in order to produce defined shorts to protect circuits and installations.

Conventional fault arc detection systems evaluate the emission of light produced by the arc and thereby detect the fault arc.

### SUMMARY

The inventors have recognized that the conventional fault arc detection systems have a disadvantage wherein optical fibers or optical detection systems need to be laid parallel to the electrical lines or power rails in order to detect any fault arcs that occur.

At least one embodiment of the present invention demonstrates an opportunity for fault arc detection.

Embodiments of the present invention are directed to a fault arc detection unit, a circuit breaker, a short-circuiter and a method.

According to at least one embodiment of the present invention, there is provision for a fault arc detection unit for a low voltage electrical circuit to have at least one voltage sensor, for periodically ascertaining electrical voltage values (un, un−1) of the electrical circuit, and an evaluation unit connected thereto. The evaluation unit is configured such that the change in voltage with respect to time is ascertained from the ascertained voltage values. The change in the voltage with respect to time is compared with threshold values, and values above or values below a threshold value result in a fault arc detection signal being delivered.

According to at least one embodiment of the present invention, there is provision for a fault arc detection unit for a low-voltage electrical circuit, comprising:
at least one voltage sensor, to periodically ascertain electrical voltage values of the electrical circuit, the at least one voltage sensor being connected to an evaluation unit wherein, the evaluation unit being configured to
   compare the electrical voltage values periodically ascertained to a first threshold value and compare the electrical voltage values periodically ascertained to a second threshold value,
wherein, a fault arc detection signal is delivered for the electrical voltage values periodically ascertained,
   upon a change in voltage with respect to time being above a first threshold value or
   upon a change in voltage with respect to time being below a second threshold value.

According to an embodiment of the invention, a circuit breaker for a low voltage electrical circuit is further provided. The circuit breaker has a fault arc detection unit according to an embodiment of the invention. The fault arc detection unit is connected to the circuit breaker, these being configured such that delivery of a fault arc detection signal results in the circuit breaker tripping, i.e. interrupting the electrical circuit. Extinguishing of the fault arc can therefore be achieved. If the circuit breaker has an electronic trip unit, very fast tripping of the circuit breaker can be achieved when a fault arc detection signal is present. This has the particular advantage that a circuit breaker is extended by a further, advantageous functionality for protecting electrical installations. In this instance, the detection and isolation of fault arcs are advantageously effected in one device. If need be, available assemblies, such as voltage and/or current sensors, power supply unit, microprocessors for the evaluation unit, etc., can also be used and can thus attain synergies.

According to an embodiment of the invention, a short-circuiter, having a fault arc detection unit connected to the short-circuiter, is further provided. These are configured such that delivery of a fault arc detection signal results in the short-circuiter shorting the electrical circuit in order to cause extinguishing of the fault arc.

According to an embodiment of the invention, a method for fault arc detection for an electrical circuit is furthermore provided. This involves periodically ascertaining electrical voltage values (un, un−1) of the circuit. These are used to continually ascertain the change in the voltage with respect to time. If the voltage is above a first threshold value (SW1), for example in the case of a positive change in the voltage with respect to time, or if the voltage is below a second threshold value (SW2), for example in the case of a negative change in the voltage with respect to time, a fault arc detection signal is delivered.

According to an embodiment of the invention, a method for fault-arc detection for an electrical circuit, comprises:
periodically ascertaining electrical voltage values of the circuit;
comparing a change in voltage with respect to time, of the electrical voltage values periodically ascertained, to a first threshold value;
comparing a change in voltage with respect to time, of the electrical voltage values periodically ascertained, to a second threshold value; and
delivering a fault arc detection signal upon the comparing indicating the change in voltage with respect to time, of the electrical voltage values periodically ascertained, being above the threshold or below the second threshold.

### BRIEF DESCRIPTION OF THE DRAWINGS

The described properties, features and advantages of this invention and the way in which they are achieved will become clearer and more distinctly comprehensible in conjunction with the description of the example embodiments that follows, the example embodiments being explained in more detail in conjunction with the drawings, in which:

FIG. 1 shows a graph of the voltage and current waveforms following arc ignition,

FIG. 2 shows a flowchart for fault arc detection,

FIG. 3 shows a block diagram of a solution according to an embodiment of the invention,

FIG. 4 shows a first depiction to explain the use of an embodiment of the invention,

FIG. 5 shows a second depiction to explain the use of an embodiment of the invention, and

FIG. 6 shows a third depiction to explain the use of an embodiment of the invention.

### DETAILED DESCRIPTION OF THE EXAMPLE EMBODIMENTS

According to at least one embodiment of the present invention, there is provision for a fault arc detection unit for a low voltage electrical circuit to have at least one voltage sensor, for periodically ascertaining electrical voltage values (un, un−1) of the electrical circuit, and an evaluation unit connected thereto. The evaluation unit is configured such that the change in voltage with respect to time is ascertained from the ascertained voltage values. The change in the voltage with respect to time is compared with threshold values, and values above or values below a threshold value result in a fault arc detection signal being delivered.

By way of example, a value above a first threshold value (SW1) for the change in the voltage with respect to time can result in a fault arc detection signal being delivered. Alternatively, a value below a second threshold value (SW2) for the change in the voltage with respect to time can result in a fault arc detection signal being delivered. The magnitudes of the two threshold values may be identical in this instance, the arithmetic sign being different.

A fundamental aspect is that sudden voltage changes or rapid changes in the voltage that are above (e.g. in the case of positive voltage changes) or below (e.g. in the case of negative voltage changes or the negative half-cycle) a threshold are detected and lead to a fault arc detection signal. Fault arcs have very sudden voltage changes when the arc ignites. These are detected according to the invention and result in delivery of a fault arc detection signal.

Advantageous configurations of the invention are specified in the claims.

In one advantageous configuration of an embodiment of the invention, the evaluation unit is configured such that a voltage difference (dun) is continually ascertained from two temporally successive voltage values (un, un−1). The voltage difference (dun) is divided by the difference in the voltage values (un, un−1) with respect to time (dtn). The thus ascertained first difference quotient (Dqun), as a measure of the change in the voltage with respect to time, is compared with the first threshold value (SW1). Values above the first threshold value result in a fault arc detection signal being delivered.

This has the particular advantage that when the preceding voltage value (un−1) is subtracted from the present voltage value (un), rising edges of the voltage result in the difference quotient becoming positive, so that fault arc ascertainment is performed for positive changes in the voltage with respect to time that are above the threshold value. That is to say that changes relating to positive changes, or the rising edge, in the voltage (in the case of the sine wave the range from 0° to 90° and 270° to 360°) are detected. There is therefore a simple opportunity for ascertainment available.

In one advantageous configuration of an embodiment of the invention, the evaluation unit is configured such that a voltage difference (dun) is continually ascertained from two temporally successive voltage values (un, un−1). The voltage difference (dun) is divided by the difference in the voltage values (un, un−1) with respect to time (dtn). The difference quotient (Dqun) ascertained therefrom, as a measure of the change in the voltage with respect to time, is compared with the second threshold value (SW2). Values below the second threshold value result in a fault arc detection signal being delivered.

This has the particular advantage that when the preceding voltage value (un−1) is subtracted from the present voltage value (un), falling edges of the voltage result in the difference quotient becoming negative, so that fault arc ascertainment is performed in consideration of negative changes in the voltage with respect to time that are below the threshold value. That is to say that changes relating to negative changes, or the falling edge (in the case of the sine wave the range from 90° to 270°), in the voltage are detected. There is therefore a further simple opportunity for ascertainment available.

In one advantageous configuration of an embodiment of the invention, the evaluation unit is configured such that a voltage difference (dun) is continually ascertained from two temporally successive voltage values (un, un−1). The voltage difference (dun) is divided by the difference in the voltage values (un, un−1) with respect to time (dtn). The magnitude of the difference quotient (Dqun) ascertained therefrom, as a measure of the change in the voltage with respect to time, is compared with the first threshold value (SW1). Values above the first threshold value result in a fault arc detection signal being delivered. This has the particular advantage that fault arc ascertainment is performed for both positive and negative changes in the voltage with respect to time, since the unsigned magnitude of the change in the voltage with respect to time is evaluated. If the magnitude is above the first threshold value, a fault arc detection signal is provided. There is therefore an opportunity for ascertainment available for both positive and negative voltage changes or sudden voltage changes.

In one advantageous configuration of an embodiment of the invention, at least one current sensor is provided, which ascertains the electric current of the electrical circuit, and is connected to the evaluation unit. The evaluation unit is configured such that the current must exceed a third threshold value (SW3) in order to deliver a fault arc detection signal. That is to say that a further criterion must be satisfied, a value above the third threshold value (SW3), before a fault arc detection signal is delivered.

This has the particular advantage that more accurate detection of fault arcs is enabled, since they frequently occur only at higher currents. It is therefore possible for erroneous fault arc detection signals to be avoided, for example if rapid voltage changes occur in normal operation.

According to an embodiment of the invention, a circuit breaker for a low voltage electrical circuit is further provided. The circuit breaker has a fault arc detection unit according to an embodiment of the invention. The fault arc detection unit is connected to the circuit breaker, these being configured such that delivery of a fault arc detection signal results in the circuit breaker tripping, i.e. interrupting the electrical circuit. Extinguishing of the fault arc can therefore be achieved. If the circuit breaker has an electronic trip unit, very fast tripping of the circuit breaker can be achieved when a fault arc detection signal is present. This has the particular advantage that a circuit breaker is extended by a further, advantageous functionality for protecting electrical installations. In this instance, the detection and isolation of fault arcs are advantageously effected in one device. If need be, available assemblies, such as voltage and/or current sensors, power supply unit, microprocessors for the evaluation unit, etc., can also be used and can thus attain synergies.

According to an embodiment of the invention, a short-circuiter, having a fault arc detection unit connected to the short-circuiter, is further provided. These are configured such that delivery of a fault arc detection signal results in the short-circuiter shorting the electrical circuit in order to cause extinguishing of the fault arc.

This has the particular advantage that there is a simple, fast and effective opportunity available for extinguishing fault arcs.

According to an embodiment of the invention, a method for fault arc detection for an electrical circuit is furthermore provided. This involves periodically ascertaining electrical voltage values (un, un−1) of the circuit. These are used to continually ascertain the change in the voltage with respect to time. If the voltage is above a first threshold value (SW1), for example in the case of a positive change in the voltage with respect to time, or if the voltage is below a second threshold value (SW2), for example in the case of a negative change in the voltage with respect to time, a fault arc detection signal is delivered.

This has the particular advantage of a simple method for fault arc detection.

All configurations and features of the embodiments of the invention bring about an improvement in the detection of fault arcs or the extinguishing thereof.

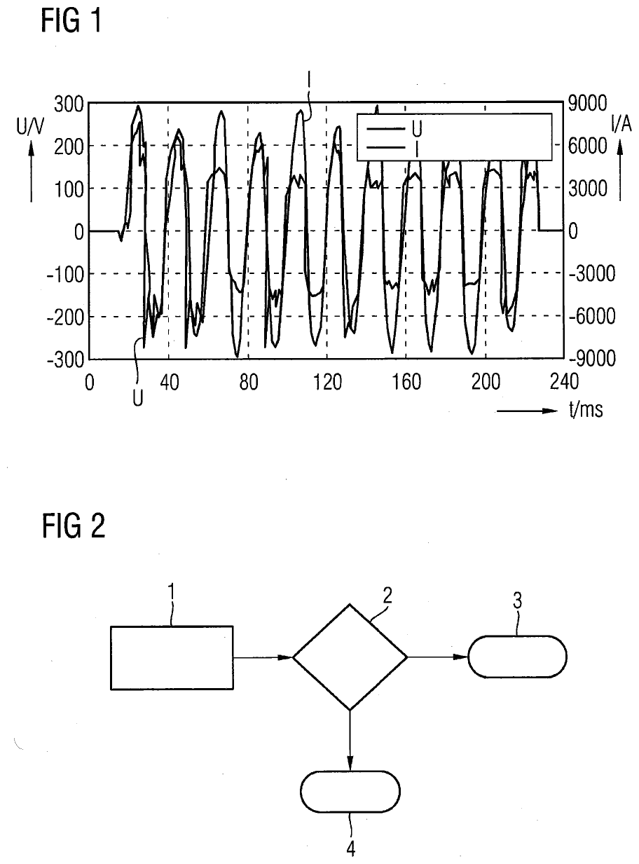

In a circuit or system in which there is a fault arc, a current and voltage profile can be measured that has a significant trend. A typical voltage and current profile for a fault arc is depicted in FIG. 1. FIG. 1 shows a depiction of a graph in which the waveform of the voltage (U) and the electric current (I) following ignition of an arc or fault arc, in particular a parallel fault arc, in an electrical circuit, in particular a low voltage circuit, is depicted.

The horizontal X axis depicts the time (t) in milliseconds (ms). The vertical Y axis depicts the magnitude of the voltage U in volts (V) on a linear scale. The right-hand scale depicts the magnitude of the electric current I in amps (A).

Following arc ignition, the current I has an approximately sinusoidal profile. The voltage (U) in this instance has a squarewave in a first approximation, instead of the usually sinusoidal profile.

In contrast to a pure sinusoidal voltage profile, a highly distorted voltage profile is obtained in circuits or systems in which there is a fault arc. From an abstract point of view, it is possible to see in the voltage profile a square-wave shape that is overlaid with a sinusoidal component—dependent on the voltage drop between the measurement point and the arc—and exhibits a highly stochastic component on the plateau. The square-wave shape is characterized in that the arc ignition and the subsequent voltage zero crossings of the AC voltage result in significantly increased voltage changes, subsequently referred to as a sudden voltage change, since the rise in the voltage change is much larger in comparison with a sinusoidal voltage profile.

According to an embodiment of the invention, the aim is for such voltage changes or sudden voltage changes to be detected, and thereupon for a fault arc detection signal to be delivered. In particular, this can involve a detection approach being taken to the effect that sudden voltage changes during arc ignition and the subsequent voltage zero crossings are detected. By way of example, a difference calculation can take place in this regard.

Voltage values (un, un−1) are ascertained continually or periodically, during which the measurement frequency or sampling frequency of the ascertained voltage values (un, un−1) should be a multiple of the frequency of the AC voltage, for example should be in the range from 1 to 200 kHz, more specifically in the range from 10 to 40 or 60 kHz, in particular in the range from 40 to 50 kHz.

The ascertained voltage values (un, un−1) are then used to perform a difference calculation, for example, with a difference quotient (Dqun) being calculated for each sample of the voltage (un). In this regard, the difference between the present voltage sample (un) and the preceding voltage sample (un−1) is formed. This difference (dun) is divided by the difference in the voltage samples (un, un−1) with respect to time (dtn), i.e. dtn=tn−tn−1, so as to obtain the difference quotient (Dqun) according to formula 1.

$$Dqun = \frac{{u}_{n} - {u}_{n - 1}}{{t}_{n} - {t}_{n - 1}} = \frac{dun}{dtn} \qquad ( 1 )$$

This difference quotient (Dqun) as a measure of the change in the voltage with respect to time is compared with a threshold value (SW). If the threshold value condition is satisfied, a fault arc detection signal occurs.

As an alternative, it is also possible for the present voltage sample (un) to be deducted from the preceding voltage sample (un−1) (dun=(un−1)−(un)). This merely changes the arithmetic sign of the difference quotient. During a comparison in which not magnitudes but rather the absolute values are compared with the threshold value, it is accordingly also necessary to pay attention to and adapt the arithmetic sign of the threshold value.

By way of example, the voltage values 30 volts (un−1) and 50 volts (un) were measured at the interval of time 20 μs, which is consistent with a sampling frequency of 50 kHz.

$$Dqun = \frac{50 volts - 30 volts}{20 μs} = 1 \frac{V}{μs}$$

The first threshold value could be 0.5 V/μs, for example.

The ascertained difference quotient 1 V/μs is above the 0.5 V/μs. A fault arc detection signal is therefore delivered.

A corresponding evaluation is depicted in FIG. 2.

According to FIG. 2, a first step (1) involves the difference quotient voltage (Dqun) being continually calculated. A second step (2) involves this being compared with the threshold value (SW). In the event of a value above the threshold value (SW), a third step (3) involves a fault arc being detected and/or a fault arc detection signal being delivered. If there are no values above the threshold value (SW), a fourth step (4) can involve it being reported that there is no fault arc or no burning fault arc present.

The calculation can be performed continually.

By way of example, according to one configuration, when signed change variables for the voltage are calculated, the comparison can be effected for positive values in consideration of their being above a first, for example positive, threshold value (SW1) and/or for negative values in consideration of their being below a second, for example negative, threshold value (SW2), that is to say if the magnitude of the negative difference is numerically greater than the magnitude of the negative threshold value.

Alternatively, a magnitude (positive) for the change in the voltage can also be formed, which is then compared with the positive first threshold value (SW1), and a value above the first threshold value results in a fault arc detection signal being delivered.

As an alternative or in addition to the fault arc detection signal, it is also possible for either “no fault arc present” or “fault arc present” to be indicated, or for a corresponding distinction to be drawn in the installation.

In addition, the fault arc detection dependent on the voltage profile according to the invention can be combined with further criteria, for example with a measurement of the electric current of the circuit. For this purpose a further sensor for current measurement is provided in the electric circuit. The measured current, in particular the RMS value of the measured current, which can be calculated using the Mann-Morrison method, for example, is in this instance compared with a third threshold value (SW3), and only if it is also above this third threshold value (SW3) and the criterion for a fault arc detection signal is satisfied is such a signal also delivered. This criterion, referred to as overcurrent release, leads to reliable fault localization. Fault arc detection requires a minimum fault arc current flow in the circuit in order to give rise to a fault arc detection signal. The threshold value chosen for the overcurrent release may be a value dependent on the operating current. Alternatively, the threshold values could also be stipulated in a manner specific to arcs, since a burning low voltage arc is accompanied by an arc current of usually at least 1000 A for parallel arcs, and currents upward of 1 A for series arcs. That is to say that the third threshold value SW3 can be stipulated upward of 1 A, 10 A, 100 A, 1000 A or 5000 A, depending on the use or application.

In one configuration, the first and/or second threshold value(s) SW1, SW2 could also be stipulated on the basis of the setting of the third threshold value SW3. That is to say that high magnitudes of the third threshold value result in the magnitudes of the first and second threshold values likewise being high.

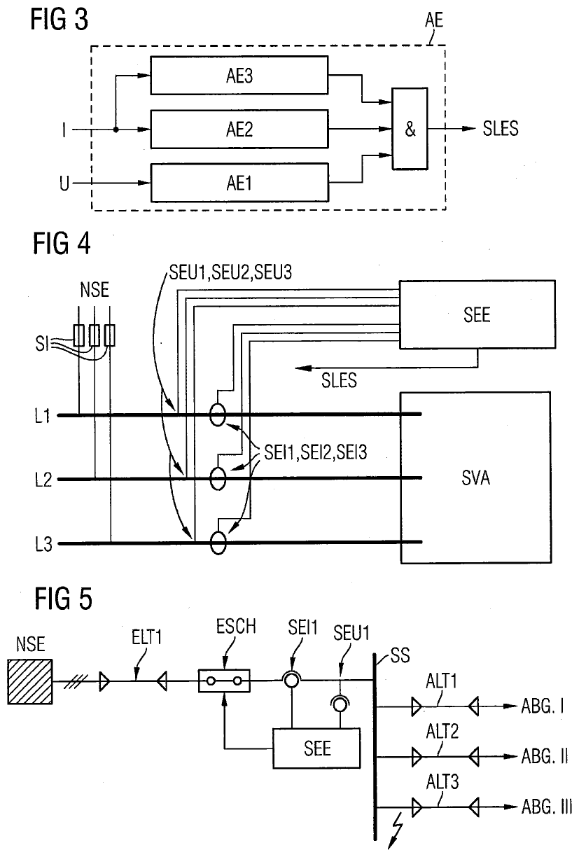

FIG. 3 shows to this end a depiction in which the ascertained voltage U of the circuit is supplied to a first evaluation unit (AE1), for ascertaining fault arcs.

The ascertained current I of the circuit is supplied to a second evaluation unit (AE2), for ascertaining a current condition, such as a value above the third current limit value (SW3).

The outputs of both units are linked to an AND unit (&), the output of which delivers a fault arc detection signal (SLES) when both criteria are satisfied.

FIG. 4 shows a schematic depiction of an outline circuit diagram for an installation configuration with an outgoing-circuit-selective fault arc detection unit for detecting fault arcs. FIG. 4 shows a low voltage incoming unit NSE, with fuses SI, which are followed by busbars L1, L2, L3 for the conductors of a three-phase AC system or circuit. The neutral conductor is not depicted. Each of the three busbars L1, L2, L3 has a respective associated voltage sensor SEU1, SEU2, SEU3 and current sensor SEI1, SEI2, SEI3. The busbars are connected to switchgear and/or a distribution installation SVA.

The voltage and current sensors are connected to a fault arc detection unit SEE according to the invention, which has an evaluation unit AE according to an embodiment of the invention. The latter has an output for delivering a fault arc detection signal SLES.

The voltage and current sensors ascertain voltage values (un, un−1) and current values (in, in−1) for the busbars L1, L2, L3 and supply them to the fault arc detection unit SEE according to the invention. The sensors in this instance are arranged outside the fault arc detection unit and connected thereto.

FIG. 5 shows a further schematic depiction of an outline circuit diagram for an installation configuration with a central fault arc detection unit for detecting fault arcs. FIG. 5 shows a low voltage incoming unit NSE that is followed by a feeder cable ELT1, which is followed by an incoming-feeder disconnector ESCH, which is followed by a current sensor SEI1 and a voltage sensor SEU1, which is followed by a busbar SS. The busbar SS has three outgoing circuits ABG I, ABG II and ABG III provided on it. These each have an associated outgoing-circuit cable ALT1, ALT2, ALT3.

The sensors SEI1, SEU1 are connected to a fault arc detection unit SEE, the output of which is in turn connected to the incoming-feeder disconnector ESCH. The incoming-feeder disconnector may in this instance be a circuit breaker. When a fault arc is detected, the electrical circuit, i.e. the supply of power to the busbar SS, can be interrupted if a fault arc occurs in one of the outgoing circuits, for example.

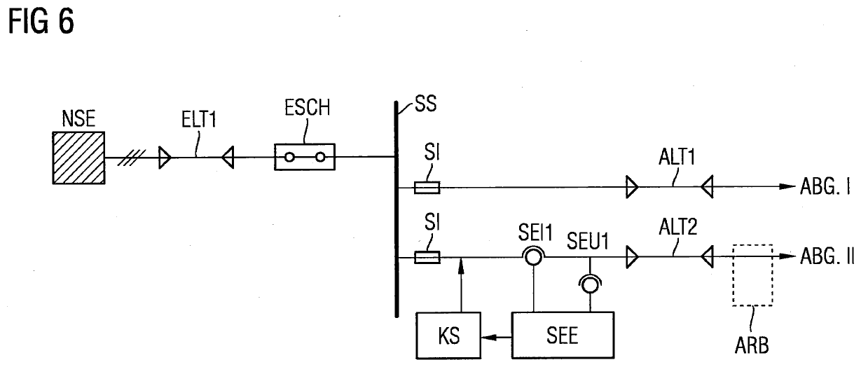

FIG. 6 shows a depiction according to FIG. 5, with the difference that the sensors are arranged in the second outgoing circuit ABG II, which also has fuses SI and a short-circuiter KS. The sensors SEI1 and SEU1 detect current and voltage values of the outgoing circuit ABG II and forward the values to the fault arc detection unit SEE. If the fault arc detection unit SEE detects a fault arc, its output delivers a fault arc detection signal, which is transmitted to the short-circuiter KS. The latter then shorts the outgoing circuit ABG II in order to extinguish the fault arc.

The fault arc detection system according to FIG. 5 or 6 may be embodied as a mobile system, for example.

An embodiment of the invention will be explained once again below.

An embodiment of the invention can be used to detect fault arcs, in particular parallel or high-current fault arcs, in particular in low voltage switchgear and distribution installations. According to an embodiment of the invention, in particular a numerical solution or detection algorithm is available for this purpose on the basis of the evaluation of measured voltage values or signals. For the detection of fault arcs, the voltage is measured and is evaluated using a signal profile analysis. Owing to the fast arc detection required in practice, an extraordinarily fast temporal evaluation can be provided for this according to an embodiment of the invention.

An embodiment of the invention allows high-current fault arcs, for example in switchgear and distribution installations, e.g. in the low voltage, to be quickly detected on the basis of a central voltage measurement at the incoming unit, for example.

An embodiment of the invention can in particular be advantageously used in circuit breakers or short-circuiters.

Complex installation of optical fibers in installations for fault arc detection is not required. The voltage measurement can be realized centrally and if need be used synergistically by further resources.

Furthermore, implementation in existing switchgear and distribution installations is a simple matter, since a detection system according to the invention can be installed just centrally, for example, and there is no need for installation in individual cells that are to be protected.

An embodiment of the invention may be implemented as an assembly with central voltage measurement.

The detection systems established on the market to date are based on optical fault detection and therefore have potential for erroneous tripping as a result of the influence of extraneous light (e.g. flashlight). This hazard potential does not exist with the solution according to the invention based on a voltage measurement.

Although the invention has been illustrated and described in greater detail by the example embodiment, the invention is not limited by the disclosed examples, and other variations can be derived therefrom by a person skilled in the art without departing from the scope of protection of the invention.

1. A fault arc detection unit for a low-voltage electrical circuit, comprising:
at least one voltage sensor, to periodically ascertain electrical voltage values of the electrical circuit, the at least one voltage sensor being connected to an evaluation unit, the evaluation unit being configured to
compare the electrical voltage values periodically ascertained to a first threshold value and compare the electrical voltage values periodically ascertained to a second threshold value,
wherein, a fault arc detection signal is delivered for the electrical voltage values periodically ascertained,
upon a change in voltage with respect to time being above a first threshold value or
upon a change in voltage with respect to time being below a second threshold value.

2. The fault arc detection unit of claim 1, wherein voltage differences are continually ascertained, each of the voltage differences being ascertained from two temporally successive voltage values of the electrical voltage values periodically ascertained with respect to time, the voltage differences being divided by a difference in the voltage values of the electrical voltage values periodically ascertained with respect to time, and wherein difference quotients, ascertained from the voltage differences continually ascertained, as a measure of a change in voltage with respect to time, are compared with the first threshold value, resulting in the fault arc detection signal being delivered upon the difference quotients being above the first threshold.

3. The fault arc detection unit of claim 1, wherein voltage differences are continually ascertained, each of the voltage differences being ascertained from two temporally successive voltage values of the electrical voltage values periodically ascertained with respect to time, the voltage differences being divided by a difference in the voltage values of the electrical voltage values periodically ascertained with respect to time, and wherein difference quotients, ascertained from the voltage differences continually ascertained as a measure of a change in voltage with respect to time, are compared with the second threshold value, resulting in the fault arc detection signal being delivered upon the difference quotients being below the second threshold value.

4. The fault arc detection unit of claim 1, wherein voltage differences are continually ascertained, each of the voltage differences being ascertained from two temporally successive voltage values of the electrical voltage values periodically ascertained with respect to time, the voltage differences being divided by a difference in the voltage values of the electrical voltage values periodically ascertained with respect to time, and wherein magnitudes of difference quotients, ascertained the voltage differences continually ascertained as a measure of a change in voltage with respect to time, are compared with the first threshold value, resulting in the fault arc detection signal being delivered upon the magnitudes of the difference quotients being above the first threshold value.

5. The fault arc detection unit of claim 1, further comprising:
at least one current sensor, to ascertain electric current of the circuit, the at least one current sensor being connected to the evaluation unit, the evaluation unit being further configured to
compare the electric current values periodically ascertained to a third threshold value, wherein the fault arc detection signal is delivered for the electrical current values periodically ascertained upon the electric current values periodically ascertained being above the third threshold value.

6. A circuit breaker for a low voltage electrical circuit, the circuit breaker comprising:
the fault arc detection unit of claim 1, connected to the circuit breaker, configured such that delivery of the fault arc detection signal results in the circuit breaker tripping to interrupt the low voltage electrical circuit.

7. A short-circuiter, comprising:
the fault arc detection unit of claim 1, connected to the short-circuiter, configured such that delivery of the fault arc detection signal results in the short-circuiter shorting the low voltage electrical circuit to cause extinguishing of a fault arc.

8. A method for fault-arc detection for an electrical circuit, comprising:
periodically ascertaining electrical voltage values of the electrical circuit;
comparing a change in voltage with respect to time, of the electrical voltage values periodically ascertained, to a first threshold value;
comparing a change in voltage with respect to time, of the electrical voltage values periodically ascertained, to a second threshold value; and
delivering a fault arc detection signal upon the comparing indicating the change in voltage with respect to time, of the electrical voltage values periodically ascertained, being above the threshold or below the second threshold.

9. The method of claim 8, wherein
voltage differences are continually ascertained from two temporally successive voltage values of the electrical voltage values periodically ascertained,
the voltage differences being divided by differences in the voltage values of the electrical voltage values periodically ascertained with respect to time, to ascertain
difference quotients indicating a measure of change in the voltage with respect to time, the difference quotients ascertained being compared with the first threshold value, wherein difference quotients above the first threshold value result in the delivering of the fault arc detection signal.

10. The method of claim 8, wherein
voltage differences are continually ascertained from two temporally successive voltage values of the electrical voltage values periodically ascertained,
the voltage differences being divided by differences in the voltage values of the electrical voltage values periodically ascertained with respect to time, to ascertain
difference quotients indicating a measure of change in the voltage with respect to time, the difference quotients ascertained being compared with compared with the second threshold value, wherein difference quotients
below the second threshold value result in the delivering of the fault arc detection signal.

11. The method of claim 8,
voltage differences are continually ascertained from two temporally successive voltage values of the electrical voltage values periodically ascertained,
the voltage differences being divided by differences in the voltage values of the electrical voltage values periodically ascertained with respect to time, to ascertain
magnitudes of difference quotients indicating a measure of change in the voltage with respect to time, the magnitudes of the difference quotients ascertained being compared with the first threshold value, wherein magnitudes of the difference quotients
above the first threshold value result in the delivering of the fault arc detection signal.

12. The method of claim 8,
further comprising:
periodically ascertaining electrical current values of the electrical circuit; and
comparing the electrical current values periodically ascertain with a third threshold value; and
delivering the fault arc detection signal upon the comparing, the electrical current values periodically ascertained, indicating
that the electrical current values periodically ascertained are the third threshold value.

13. The method of claim 8,
wherein
the fault arc detection signal is used to interrupt or short the electrical circuit.

14. The fault arc detection unit of claim 2, further comprising:
at least one current sensor, to ascertain electric current of the circuit, the at least one current sensor being connected to the evaluation unit, the evaluation unit being further configured to
compare the electric current values periodically ascertained to a third threshold value, wherein the fault arc detection signal is delivered for the electrical current values periodically ascertained upon the electric current values periodically ascertained being above the third threshold value.

15. The fault arc detection unit of claim 3, further comprising:
at least one current sensor, to ascertain electric current of the circuit, the at least one current sensor being connected to the evaluation unit, the evaluation unit being further configured to
compare the electric current values periodically ascertained to a third threshold value, wherein the fault arc detection signal is delivered for the electrical current values periodically ascertained upon the electric current values periodically ascertained being above the third threshold value.

16. The fault arc detection unit of claim 4, further comprising:
at least one current sensor, to ascertain electric current of the circuit, the at least one current sensor being connected to the evaluation unit, the evaluation unit being further configured to
compare the electric current values periodically ascertained to a third threshold value, wherein the fault arc detection signal is delivered for the electrical current values periodically ascertained upon the electric current values periodically ascertained being above the third threshold value.

17. A circuit breaker for a low voltage electrical circuit, the circuit breaker comprising:
the fault arc detection unit of claim 2, connected to the circuit breaker, configured such that delivery of the fault arc detection signal results in the circuit breaker tripping to interrupt the low voltage electrical circuit.

18. A short-circuiter, comprising:
the fault arc detection unit of claim 2, connected to the short-circuiter, configured such that delivery of the fault arc detection signal results in the short-circuiter shorting the low voltage electrical circuit to cause extinguishing of a fault arc.

19. A circuit breaker for a low voltage electrical circuit, the circuit breaker comprising:
the fault arc detection unit of claim 3, connected to the circuit breaker, configured such that delivery of the fault arc detection signal results in the circuit breaker tripping to interrupt the low voltage electrical circuit.

20. A short-circuiter, comprising:
the fault arc detection unit of claim 3, connected to the short-circuiter, configured such that delivery of the fault arc detection signal results in the short-circuiter shorting the low voltage electrical circuit to cause extinguishing of a fault arc.

21. A circuit breaker for a low voltage electrical circuit, the circuit breaker comprising:
the fault arc detection unit of claim 4, connected to the circuit breaker, configured such that delivery of the fault arc detection signal results in the circuit breaker tripping to interrupt the low voltage electrical circuit.

22. A short-circuiter, comprising:
the fault arc detection unit of claim 4, connected to the short-circuiter, configured such that delivery of the fault arc detection signal results in the short-circuiter shorting the low voltage electrical circuit to cause extinguishing of a fault arc.

23. A circuit breaker for a low voltage electrical circuit, the circuit breaker comprising:
the fault arc detection unit of claim 5, connected to the circuit breaker, configured such that delivery of the fault arc detection signal results in the circuit breaker tripping to interrupt the low voltage electrical circuit.

24. A short-circuiter, comprising:
the fault arc detection unit of claim 5, connected to the short-circuiter, configured such that delivery of the fault arc detection signal results in the short-circuiter shorting the low voltage electrical circuit to cause extinguishing of a fault arc.

25. The method of claim 9, further comprising:
periodically ascertaining electrical current values of the electrical circuit; and
comparing the electrical current values periodically ascertain with a third threshold value; and
delivering the fault arc detection signal upon the comparing, the electrical current values periodically ascertained, indicating that the electrical current values periodically ascertained are the third threshold value.

26. The method of claim 9, wherein the fault arc detection signal is used to interrupt or short the electrical circuit.

27. The method of claim 10, further comprising:
periodically ascertaining electrical current values of the electrical circuit; and
comparing the electrical current values periodically ascertain with a third threshold value; and
delivering the fault arc detection signal upon the comparing, the electrical current values periodically ascertained, indicating that the electrical current values periodically ascertained are the third threshold value.

28. The method of claim 10, wherein the fault arc detection signal is used to interrupt or short the electrical circuit.

29. The method of claim 11, further comprising:
periodically ascertaining electrical current values of the electrical circuit; and
comparing the electrical current values periodically ascertain with a third threshold value; and
delivering the fault arc detection signal upon the comparing, the electrical current values periodically ascertained, indicating that the electrical current values periodically ascertained are the third threshold value.

30. The method of claim 11, wherein the fault arc detection signal is used to interrupt or short the electrical circuit.

31. The method of claim 12, wherein the fault arc detection signal is used to interrupt or short the electrical circuit.
